(19) United States
(12) Patent Application Publication
(10) Pub. No.: US 2014/0170805 A1
(43) Pub. Date: Jun. 19, 2014

(54) Thermal Processing Utilizing Independently Controlled Elemental Reactant Vapor Pressures and/or Indirect Cooling

(71) Applicant: HelioVolt Corporation, Austin, TX (US)

(72) Inventors: Michael Floyd Miller, Pflugerville, TX (US); Baosheng Sang, Austin, TX (US); Dingyuan Lu, Austin, TX (US); Billy J. Stanbery, Austin, TX (US)

(21) Appl. No.: 13/919,228

(22) Filed: Jun. 17, 2013

Related U.S. Application Data
(60) Provisional application No. 61/737,417, filed on Dec. 14, 2012.

(51) Int. Cl. H01L 31/18; H01L 31/032

(52) U.S. Cl. CPC H01L 31/18; H01L 31/0322
USPC 438/95; 118/719

(57) ABSTRACT

A machine includes a thermal ramp chamber; a thermal soak chamber coupled to the thermal ramp chamber; and a cooling chamber coupled to the thermal soak chamber. The cooling chamber can be an indirect cooling chamber including a thermal buffer that includes a substrate carrier. Each of the chambers can include an independently controlled elemental reactant source containing and supplying vapor having both i) independent control of a total vapor pressure of an elemental reactant containing vapor and ii) independent control of a partial vapor pressure of an elemental reactant vapor within that chamber.

### CROSS-REFERENCE TO RELATED APPLICATION

Referring to the application data sheet filed herewith, this application claims a benefit of priority under 35 U.S.C. 119(e) from copending provisional patent application U.S. Ser. No. 61/737,417, filed Dec. 14, 2012, the entire contents of which are hereby expressly incorporated herein by reference for all purposes.

### BACKGROUND

There are selenization procedures using hydrogen selenide (H₂Se) gas to fabricate Cu(In₁₋ₓGaₓ)Se₂ (GIGS) films for use in solar panels. Typically, these procedures use Cu—In—Ga (CIG) precursors and H₂Se gas as a selenium source, which is highly toxic and requires costly delivery systems to maintain safety protocols. A problem with this technology has been the large thermal budget required to heat the precursors. Another problem with this technology has been the safety and environmental issues raised by the use of H₂Se gas.

In typical commercial batch processing selenization equipment, it takes about an hour to process substrates with CIG or CIGS precursors due slow heating and cooling rates, resulting in long processing time, which can result in high capital equipment expenditure. Furthermore, batch processing can result in poor cooling uniformity and cause substrate bowing and/or warping, reducing the product yields. In typical inline commercial selenization equipment, the footprint is very large and the operating cost is very high because of the slow heating and cooling rates required.

One unsatisfactory approach, in an attempt to solve the thermal budget problem, involves selenization procedures that consist of rapid thermal ramping, followed by high-temperature soaking in a reduced pressure and/or atmospheric environment. However, this approach does not result in formation of an optimal CIGS absorber layer.

Heretofore, the requirement(s) of uniform surface treatment and optimization of the bulk electronic properties referred to above have not been fully met. In view of the foregoing, there is a need in the art for a solution that simultaneously solves both of these problems when fabricating CIGS films for use in solar panels.

### SUMMARY

There is a need for the following embodiments of the present disclosure. Of course, the present disclosure is not limited to these embodiments.

According to an embodiment of the present disclosure a method comprises: transferring a substrate from a loadlock into a thermal ramp chamber; then thermally processing the substrate in the thermal ramp chamber wherein the thermal ramp chamber includes a first independently controlled elemental reactant source containing and supplying vapor having both i) independent control of a total vapor pressure of a first elemental reactant containing vapor and ii) independent control of a partial vapor pressure of first elemental reactant vapor within the thermal ramp chamber; then transferring the substrate from the thermal ramp chamber to a thermal soak chamber; then soaking the substrate in the thermal soak chamber wherein the thermal soak chamber includes a second independently controlled elemental reactant source containing and supplying vapor having both i) independent control of a total vapor pressure of a second elemental reactant containing vapor and ii) independent control of a partial vapor pressure of a second elemental reactant vapor within the thermal soak chamber; then transferring the substrate from the thermal soak chamber to a cooling chamber; and then cooling the substrate in the cooling chamber wherein the cooling chamber includes a third independently controlled elemental reactant source containing and supplying vapor having both i) independent control of a total vapor pressure of a third elemental reactant containing vapor and ii) independent control of a partial vapor pressure of a third elemental reactant vapor within the cooling chamber. Optionally, the first elemental reactant vapor includes at least one member selected from the group consisting of selenium, sulfur and/or sodium, the second elemental reactant vapor includes at least one member selected from the group consisting of selenium, sulfur and/or sodium, the third elemental reactant vapor includes at least one member selected from the group consisting of selenium, sulfur and/or sodium and the film includes at least one member selected from the group consisting of copper, indium, gallium and/or selenium.

According to another embodiment of the present disclosure an apparatus comprises: a thermal ramp chamber including a first independently controlled elemental reactant source containing and supplying vapor having both i) independent control of a total vapor pressure of a first elemental reactant containing vapor and ii) independent control of a partial vapor pressure of a first elemental reactant vapor within the thermal ramp chamber; a thermal soak chamber coupled to the thermal ramp chamber, the thermal soak chamber including a second independently controlled elemental reactant source containing and supplying vapor having both i) independent control of a total vapor pressure of a second elemental reactant containing vapor and ii) independent control of a partial vapor pressure of a second elemental reactant vapor within the soak chamber; and a cooling chamber coupled to the thermal soak chamber, the cooling chamber including a third independently controlled elemental reactant source containing and supplying vapor having both i) independent control of a total vapor pressure of a third elemental reactant containing vapor and ii) independent control of a partial vapor pressure of a third elemental reactant vapor within the cooling chamber.

According to another embodiment of the present disclosure a method comprises: transferring a substrate from a loadlock into a thermal ramp chamber; then thermally processing the substrate in the thermal ramp chamber; then transferring the substrate from the thermal ramp chamber into a thermal soak chamber; then soaking the substrate in the thermal soak chamber; then transferring the substrate from the thermal soak chamber into an indirect cooling chamber, and then cooling the substrate on the substrate carrier in the indirect cooling chamber while the substrate is located within a thermal buffer that surrounds the substrate carrier.

According to another embodiment of the present disclosure, a machine comprises: a thermal ramp chamber; a thermal soak chamber coupled to the thermal ramp chamber; and an indirect cooling chamber coupled to the thermal soak chamber, the indirect cooling chamber including a thermal buffer that includes a substrate carrier.

These, and other, embodiments of the present disclosure will be better appreciated and understood when considered in conjunction with the following description and the accompanying drawings. It should be understood, however, that the following description, while indicating various embodiments of the present disclosure and numerous specific details thereof, is given for the purpose of illustration and does not imply limitation. Many substitutions, modifications, additions and/or rearrangements may be made within the scope of embodiments of the present disclosure, and embodiments of the present disclosure include all such substitutions, modifications, additions and/or rearrangements.

### BRIEF DESCRIPTION OF THE DRAWINGS

The drawings accompanying and forming part of this specification are included to depict certain embodiments of the present disclosure. A clearer concept of the embodiments described in this application will be readily apparent by referring to the exemplary, and therefore nonlimiting, embodiments illustrated in the drawings (wherein identical reference numerals (if they occur in more than one view) designate the same elements). The described embodiments may be better understood by reference to one or more of these drawings in combination with the following description presented herein. It should be noted that the features illustrated in the drawings are not necessarily drawn to scale.

FIG. 1 is a schematic view of a machine for performing a selenization process on a CIGS absorber layer film on a substrate.

FIG. 2 is a schematic view of the selenization portion of the apparatus shown in FIG. 1.

FIG. 3 is a schematic view of the thermal ramp chamber of the selenization portion shown in FIG. 2.

FIGS. 4A-4B are schematic views of the indirect cooling chamber of the selenization portion shown in FIG. 2.

### DETAILED DESCRIPTION

Embodiments presented in the present disclosure and the various features and advantageous details thereof are explained more fully with reference to the nonlimiting embodiments that are illustrated in the accompanying drawings and detailed in the following description. Descriptions of well known starting materials, processing techniques, components and equipment are omitted so as not to unnecessarily obscure the embodiments of the present disclosure in detail. It should be understood, however, that the detailed description and the specific examples are given by way of illustration only and not by way of limitation. Various substitutions, modifications, additions and/or rearrangements within the scope of the underlying inventive concept will become apparent to those skilled in the art from this disclosure.

Heretofore, there does not exist a high-throughput, cost-effective selenization solution for CIGS solar panels that provides a rapid thermal ramping, a uniform high-temperature soaking, and an indirect cooling in a reduced pressure environment, with independently controlled elemental selenium partial pressure and thermal (temperature) environments. The use of reduced pressure and independently controlled thermal environments combined with independently controlled total pressure and selenium partial pressures allow formation of an optimal CIGS absorber layer. Furthermore, the post reaction thermal dwell in the indirect cooling environment in a controlled selenium vapor pressure environment allows for uniform surface treatment and optimization of the bulk electronic properties of the CIGS.

A preferred embodiment of this disclosure can include the combination of the following three points. First, a multi-chamber sequential processing apparatus, each of whose chambers is capable of independent control of heating/cooling and partial pressure of a reactant gas or vapor (e.g. selenium). Second, after the first two (ramp and soak) chambers, the apparatus includes an indirect cooling chamber where thermal energy is removed from the substrate through the use of heat exchanger tubes that are located outside of the walls of the indirect cooling chamber. Third, all three of these chambers (i.e. ramp, soak and indirect cooling) are contained within a larger outer chamber, the total pressure of which is controlled independently (optionally at a sub-atmospheric total pressure). Of course, the invention is not limited to this particular embodiment.

A substrate with a precursor layer enters the apparatus and is introduced into a low oxygen level environment at a specific absolute pressure. Then, the substrate with precursor layer enters the ramp chamber and is elevated to a specific temperature in an independently controlled selenium vapor environment at a specific partial pressure (P^{Se}_{RTP}). After the initial temperature increase in the ramp chamber, the substrate and film is transferred into a soak chamber at another independently controlled selenium partial pressure (P^{Se}_{SOAK}) to optimize film growth/formation. After the soak chamber, the substrate and film is transferred into an indirect cooling chamber, at another independently controlled selenium partial pressure (P^{Se}_{IC}). These independent partial pressures are enabled by three separate independent selenium sources. Each of these selenium sources has independent temperature controls and carrier gas mass flow controllers. These selenium sources can take many forms such as pure element or gas mixtures.

Indirect cooling means thermal energy is removed from the substrate and CIGS layer using a cooling media circulating through closed tubes that are separated from the substrate and reaction environment by chamber walls of the indirect cooling chamber. The indirect cooling chamber and/or walls can be made of graphite, for example. The cooling media does not mix with the gases in the indirect cooling chamber containing, where the substrate and CIGS layer resides, or with those gases in the outer chamber, whose pressure is independently controlled. The thermal energy from the substrate and CIGS layer are absorbed by the graphite walls of the indirect cooling chamber and then transferred through the walls of cooling tubes to the heat transfer media within them. The indirect cooling chamber enables the substrate temperature to be reduced to a dwell temperature less than the temperature of the soak chamber.

All three of these chambers are enclosed within an outer chamber, the internal total pressure (P_{TOT}) of which can be controlled to be at or below atmospheric pressure and is independent of the pressures (P^{Se}_{RTP}, P^{Se}_{SOAK}, P^{Se}_{IC}) of the three chambers within it.

The independence of temperature and selenium partial pressure control within each of the chambers, ramp, soak, and indirect cool, allows for control of optimized CIGS layer.

Furthermore, the addition of the indirect cooling apparatus, the substrate and fully selenized CIGS layer will allow for rapid removal of thermal energy in a controlled selenium environment.

This rapid removal of thermal energy in a controlled selenium environment will allow for higher throughputs (faster processing times) and improve GIGS bulk properties.

The use of multiple indirect cooling chambers, as opposed to one, adjacent to one another will allow for a rapid multi-staged cooling ability. This could further assist in reducing the processing time and increasing production throughput.

An alternative use of indirect cooling can utilize a uniform cooling loop/s that is in direct contact with the inner chamber, but still maintains isolation from the process gases and substrate environment. This would involve the use of a heat exchange media that is pushed or pumped through the cooling loop/s.

There exist options for many alternative heat exchange media, such as water, air, nitrogen, helium, compressed gases and oils, such as synthetics/aromatics, silicone-based or fluorinated oils. These alternatives can be matched to the design and process requirements, offering a wide variety of heat exchange capacities.

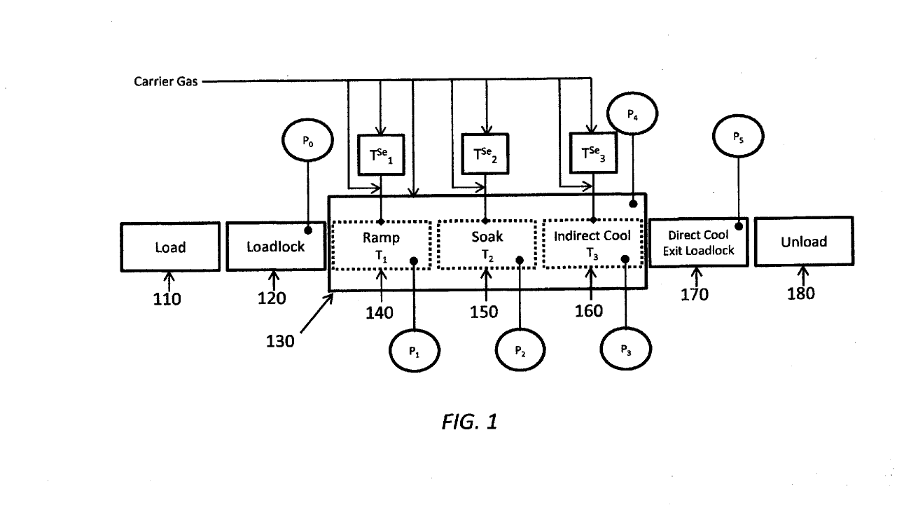

Referring to FIG. 1, a load section 110 is coupled to a loadlock section 120. An enclosure 130 is coupled to the loadlock section 120. The enclosure 130 includes a thermal ramp chamber 140 coupled to the loadlock section 120. The enclosure 130 includes a thermal soak chamber 150 coupled to the thermal ramp chamber 140. The enclosure 130 includes an indirect cooling chamber 160 coupled to the thermal soak chamber 150. A direct cooling chamber and loadlock section 170 is coupled to the indirect cooling chamber 160. An unload section 180 is coupled to the direct cooling chamber 170.

Still referring to FIG. 1, please note that the process flow is from left-to-right in FIG. 1. First, a substrate with precursor films will enter the apparatus and be staged on the load section (110).

The load section (110) is considered to be in an open standard atmospheric environment,

Second, the substrate, will be transferred to the loadlock where undesirable reactants/gases are removed from the substrate environment, such as oxygen (O₂). The loadlock pressure (P₀) is matched to the enclosure pressure (P₄) . Third, the substrate will be transferred to the thermal ramp chamber (140) and be ramped up to an elevated temperature in a controlled selenium vapor environment and partial pressure (P₁). Fourth, the substrate will be transferred into the thermal soak chamber (150), with an independently controlled selenium vapor environment and partial pressure (P₂) to optimize film growth. Fifth, the substrate will be transferred to a third thermal chamber where in during a cooling process, with an additional independently controlled selenium vapor pressure environment and partial pressure (P₃), will complete the CIGS synthesis process and provide both optimized bulk and surfaces of the absorber layer. This tertiary annealing step during cool down can be termed indirect cooling. Sixth, the substrate will be transferred to the direct cool exit loadlock (170) where excess selenium vapor is removed from the substrate environment and the substrate is cooled to even lower temperatures. Lastly, the direct cool exit loadlock pressure (P₅) will be controlled to match an open atmospheric environment of which the unload section (180) resides. The substrate will then be transferred to the unload section (180).

The incorporation of controlled rapid heating, uniform soaking, and indirect cooling at unique temperatures coupled with independently controlled stoichiometric mixtures (e.g. nitrogen gas with selenium vapor) and independently controlled reactant (e.g. selenium) partial pressures will allow for growth of optimized CIGS structures. The reduced pressure environment allows for a denser film, a decrease in oxide growth, a decrease of voids in the CIGS film structure and improved large area uniformity. Furthermore, the use of elemental selenium will allow for a decrease in operational cost and capital expenditures when compared to the alternative approach of Hydrogen Selenide (H₂Se) thermal processing with its associated legal permitting, hazardous material issues, and costly delivery and safety systems. The addition of an indirect cooling section will allow for a post-reaction surface treatment in situ without having to break the pressure environment or an additional post reaction surface anneal manufacturing step. The use of high speed single substrate processing allows for a faster throughput or time per substrate than conventional batch ovens.

The temperature T₁ of the thermal ramp chamber 140 can be maintained from approximately ambient (20° C.) to approximately 800° C. The temperature T₂, of the thermal soak chamber 150 can be maintained from approximately ambient (20° C.) to approximately 650° C. The temperature T₃ of the indirect cooling chamber 160 can be maintained from approximately ambient (20° C.) to approximately 650° C.

The total residence time of the substrate in the enclosure 130 can be from approximately 3 mins to approximately 50 mins (and longer). The residence time of the substrate in the thermal ramp chamber 140 at T₁ can be from approximately 45 sec to approximately 10 mins, depending on temperature of T₁. The residence time of the substrate in the thermal soak chamber 150 at T₂ can be from approximately 30 sec to approximately 20 mins. The residence time of the substrate in the indirect cooling chamber 160 at T₃ can be from approximately 30 sec to approximately 20 mins.

The enclosure 130 total pressure P₄ can be maintained at a total pressure of typically from approximately 0.1 mbar to approximately 1050 mbar. However, the lower end of this range can be much lower than this by minimizing chamber volume and/or increasing pump capacity (there are numerous readily commercially available pump technologies available). (The total pressure inside the graphite boxes (not shown in FIG. 1), P₁, P₂, P₃ are the same as P₄. They can be pressure coupled (same pressure ranges, as well). The partial pressure of Se inside the ramp (140), soak (150), and indirect cool chambers (160) is what can be different and independently controlled.

The Se₁ reactant vapor for the thermal ramp chamber 140 can be provided at a partial pressure of from approximately 0 mbar to approximately 300 mbar; and a temperature of from approximately ambient (20° C.) to approximately 600° C. The Se₂ reactant vapor for the thermal soak chamber 150 can be provided at a partial pressure of from approximately 0 mbar to approximately 300 mbar; and a temperature of from approximately ambient (20° C.) to approximately 600° C. The Se₃ reactant vapor for the indirect cooling chamber 160 can be provided at a partial pressure of from approximately 0 mbar to approximately 300 mbar; and a temperature of from approximately ambient (20° C.) to approximately 600° C. Embodiment can include the use of other and/or additional reactant vapors such as sulfur containing vapor.

The N₂ gas to be mixed with the Se₁ reactant gas can be provided at a partial pressure from approximately 0 mbar to approximately 1000 mbar; and at a temperature T^{Se}₁ of from approximately ambient (20° C.) to approximately 600° C. The N₂ gas to be mixed with the Seₑ reactant gas can be provided at a partial pressure of from approximately 0 mbar to approximately 1000 mbar; and at a temperature of from approximately ambient (20° C.) to approximately 600° C. The N₂ gas to be mixed with the Se₃ reactant gas can be provided at a partial pressure of from approximately 0 mbar to approximately 1000 mbar; and at a temperature T^{Se}₂ of from approximately ambient (20° C.) to approximately 600° C. The N₂ gas to the enclosure can be provided at a pressure of from approximately 0 mbar to approximately 1000 mbar; and at a temperature T^{Se}₃ of from approximately ambient (20° C.) to approximately 600° C. Embodiment can include the use of other and/or additional carrier gases such as Ar, He, O₂ and/or H₂, H₂O including mixtures of additional stated gases.

The exhaust from the enclosure 130 can be re-circulated (not shown). Recirculation can include filtering and purification of the exhaust gas. Recirculation can include separation of the reactant vapor from the carrier gas. Recirculation can include filtering and purification individually of the reactant gas and/or the carrier gas.

The substrate can include a precursor when the substrate enters the loadlock 120. For the processing of GIGS, the precursor can include one or more sources of copper, indium, gallium and/or selenium. Optionally, the precursor can also include one or more sources of aluminum, silver, zinc, tin, sodium and/or sulfur. The precursor can be transformed into a reaction product as the substrate advances through the enclosure. The reaction product can be a layer of GIGS.

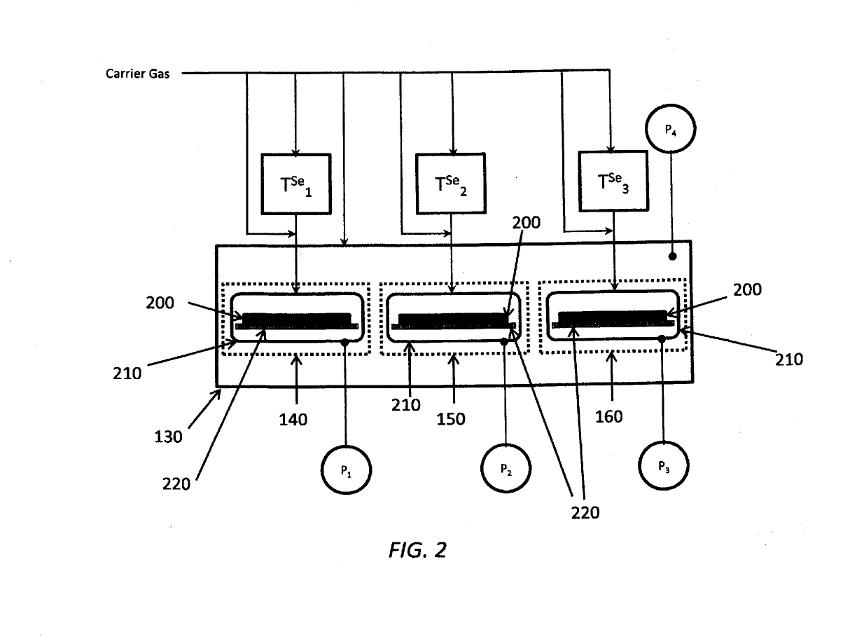

Referring to FIG. 2, embodiments of the present disclosure can include a thermal buffer 210 that surrounds the substrate 200 as the substrate is advanced through the enclosure 130. The thermal ramp chamber 140 includes a thermal buffer 210. Similarly, the thermal soak and indirect cool chamber also contains separate thermal buffers 210. The thermal buffer 210 can be a graphite box or other refractory elements, compounds or alloys, such as alumina or silicon carbide, suitable for the process requirements. The thermal buffers 210 can also be made of different materials within the ramp chamber 140, thermal soak chamber 150, and indirect cool chamber 160. The thermal buffer 210 enables both isothermal heating and indirect cooling. The thermal buffers 210 can accept a carrier 220 that is (pre)loaded (charged) with a precursor containing Cu, In, Ga and/or Se in the form of a (thin) film on a substrate 200 before entering the loadlock chamber; and is then (post)unloaded (discharged) with a resulting reaction product on the substrate after the indirect cooling chamber 160. The carrier 220 can also be made of graphite, ceramic, refractory metals, alloys or a combination there within suitable for the process requirements. The carrier 220 may or may not contain a lid. In this case, the carrier 220 with substrate 200 will pass through the thermal ramp chamber 140 and then the thermal soak chamber 150 before entering the indirect cooling chamber 160. Similarly, the substrate 200 can enter the thermal buffer 210 through the assistance of rollers or a belt. In this case the substrate 200 will pass through the thermal ramp chamber 140 and then the thermal soak chamber 150 before entering the indirect cooling chamber 160.

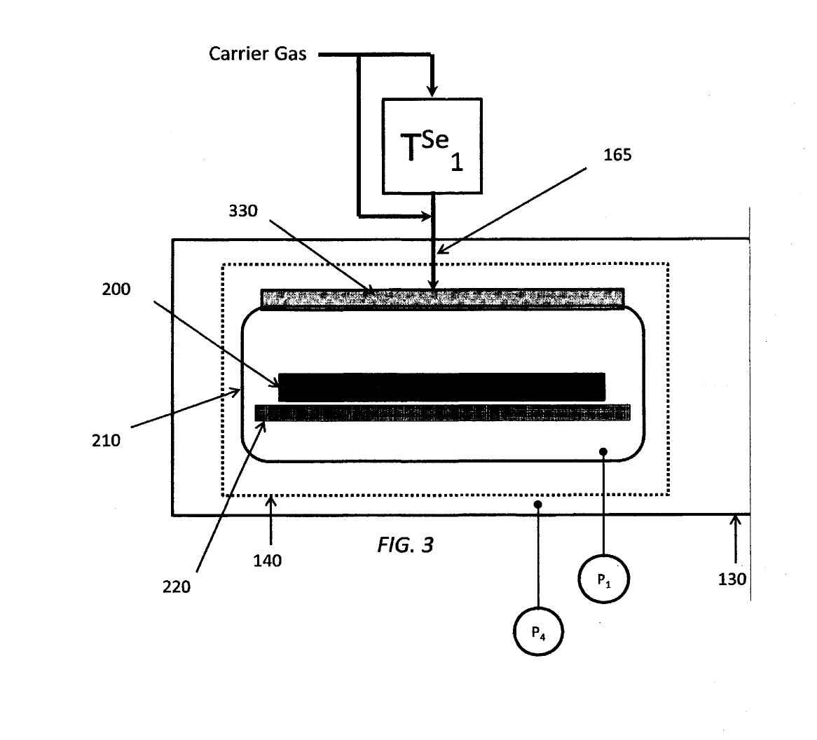

Referring to FIG. 3, the thermal ramp chamber 140 is shown in a larger scale. The thermal buffer 210, contained within the thermal ramp chamber 140, can include a manifold 330 that is reversibly coupled to a conduit 165 to convey the elemental reactant vapor and/or reactant gas toward the substrate 200 and/or carrier 220. The manifold 330 can be designed such that the reactant gas is uniformly distributed within the thermal buffer 210. The conduit 165 and manifold 330 can be made of graphite, ceramic, refractory metals, alloys or a combination there within suitable for the process requirements. The sealing of the conduit 165 and the manifold 330 can be fastened or assembled with the use of fasteners, high-temperature epoxies/pastes, and/or slip-fit designs. Similarly, the thermal soak chamber 150 and the indirect cool chamber 160 can also contain the same conduit and manifold type assemblies to deliver reactant gases. The thermal buffer 210 can at least in part protect the precursor and/or reaction product from convection currents within the chamber(s). The thermal buffer 210 can also inhibit (slow down) thermal conduction from/to the precursor and/or reaction product within the chamber(s). The thermal buffer can also inhibit (slow down) thermal radiation from/to the precursor and/or reaction product within the chamber(s). For instance, the thermal buffer can be a substantially solid baffle and/or web that 1) blocks direct line-of-sight passage between and/or 2) provides a constrained conductance between i) a volume (space) located between the inside of the buffer and the surface of the substrate and ii) another volume (space) located between the outside of the buffer and the inside of the chamber in which the buffer is located.

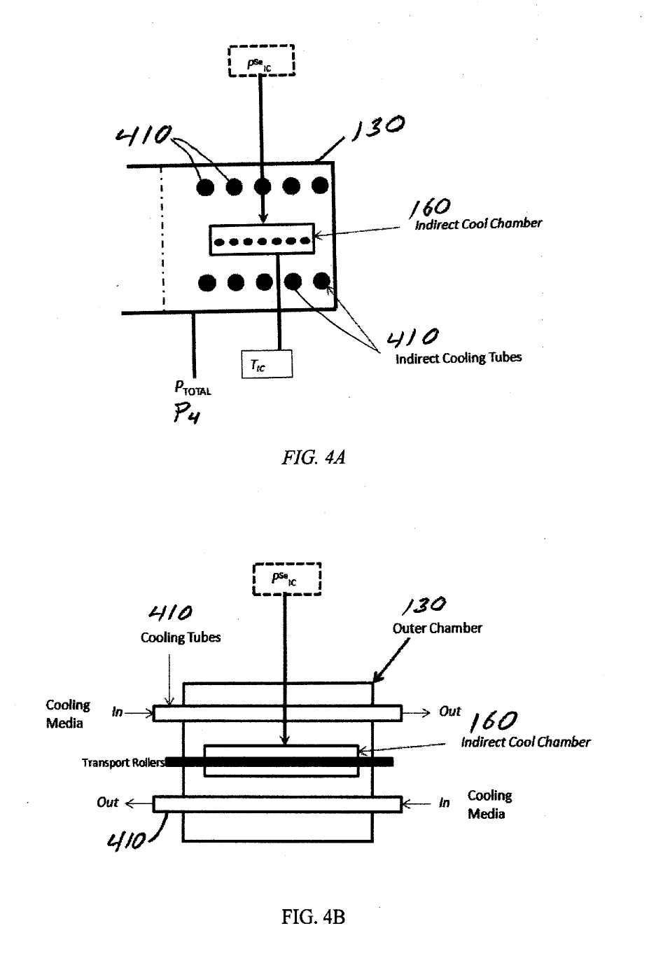

Referring to FIGS. 4A-4B, indirect cooling tubes 410 are shown close to but not touching the indirect cooling chamber 160. A cooling media flows through the cooling tubes 410. In this way, a heat exchanger is deployed to transfer heat. Of course, the invention is not limited to the example shown in FIGS. 4A-4B, or the other figures.

An embodiment of the present disclosure can utilize data processing methods that transform signals from temperature sensors to control individual temperatures associated with sections of the apparatus. For example, an embodiment of the present disclosure can be combined with temperature sensing instrumentation to obtain state variable temperature information to actuate interconnected discrete hardware elements. For instance, an embodiment of the present disclosure can include the use of heater(s) and/or cooler(s) to control the individual temperatures associated with individual sections of the apparatus.

An embodiment of the present disclosure can also utilize data processing methods that transform signals from pressure sensors to control pressures associated with individual sections of the apparatus. For example, an embodiment of the present disclosure can be combined with pressure sensing instrumentation to obtain state variable information to actuate interconnected discrete hardware elements. For instance, an embodiment of the present disclosure can include the use of mass flow controller(s), throttle/gate/pendulum valves and/or pump(s) to control the individual pressures associated with individual sections of the apparatus.

The disclosed embodiments show a single in-line batch machine as the structure for performing the functions of ramp, soak and indirect cool, but the structure for performing these functions can be any other machine capable of performing the function of ramp, soak and indirect cool, including, by way of example a series of expanding capacity first-in first out sections to provide increasing dwell times for each subsequent function; or a rotating turret with three different circumferential length sections providing corresponding different dwell times for ramp, soak and indirect cool, respectively.

### ADVANTAGES

Embodiments of the present disclosure can be cost effective and advantageous for at least the following reasons. The incorporation of controlled rapid heating and two unique soak temperatures coupled with independently controlled total pressures (inert gas, like nitrogen, with selenium vapor) and selenium partial pressures will allow for formation of optimized CIGS structures. The reduced pressure environment allows for a decrease in oxide growth, a decrease of voids in the CIGS film structure and improved large area uniformity. Furthermore, the use of elemental selenium will allow for a decrease in operational cost when compared to the alternative approach of Hydrogen Selenide (H₂Se) thermal processing with its associated legal permitting and hazardous material issues.

The addition of an indirect cooling section, with or without an active selenium pressure control, will allow for a post-reaction surface treatment in situ, without having to break the reaction pressure environment, nor will it add an additional post reaction surface anneal manufacturing step. The indirect cooling apparatus aids in providing faster and a more uniform cooling environment. Furthermore, the use of an indirect cooling section will allow for accurate control of selenium vapor to be present through the cooling of the film stack and substrate from peak reaction temperatures, reducing defects in film and film surface due to escape of selenium, which improves electronic property of CIGS film and increases electrical performance of solar panel.

Embodiments of the instant disclosure permit uniform and controlled surface treatment of the reacted CIGS. Embodiments of the instant disclosure permit optimization of the bulk electronic properties of the GIGS such as passivation of deep-level defects formed during ramp-thermal treatment.

The use of high speed single substrate processing allows for a faster throughput or time per substrate than conventional batch ovens. Embodiments of the present disclosure improve quality and/or reduce costs compared to previous approaches.

### DEFINITIONS

The phrase thermal ramp chamber (ramp chamber) is intended to mean a structure within which a substrate is uniformly heated to an elevated temperature, within a uniform pressure and stoichiometric environment, for duration of time approximately less than one minute. The term thermal soak chamber (soak chamber) is intended to mean a structure within which a substrate is allowed to dwell at a substantially constant temperature, within a uniform pressure and stoichiometric environment, for duration of time approximately greater than one minute. The phrase indirect cooling chamber (indirect chamber) is intended to mean a structure within which a substrate is uniformly cooled, within a uniform pressure and stoichiometric environment, for duration of time approximately greater than one minute.

The term uniformly is intended to mean unvarying or deviate very little from a given and/or expected value (e.g, within 10% of). The term substantially is intended to mean largely but not necessarily wholly that which is specified. The term approximately is intended to mean at least close to a given and/or expected value (e.g., within 10% of). The term coupled is intended to mean connected, although not necessarily directly, and not necessarily mechanically. The term deploying is intended to mean designing, building, shipping, installing and/or operating. The term substrate is intended to mean to product that is being processed.

The terms first or one, and the phrases at least a first or at least one, are intended to mean the singular or the plural unless it is clear from the intrinsic text of this document that it is meant otherwise. The terms second or another, and the phrases at least a second or at least another, are intended to mean the singular or the plural unless it is clear from the intrinsic text of this document that it is meant otherwise. Unless expressly stated to the contrary in the intrinsic text of this document, the term or is intended to mean an inclusive or and not an exclusive or. Specifically, a condition A or B is satisfied by any one of the following: A is true (or present) and B is false (or not present), A is false (or not present) and B is true (or present), and both A and B are true (or present). The terms a and/or an are employed for grammatical style and merely for convenience.

The term plurality is intended to mean two or more than two. The term any is intended to mean all applicable members of a set or at least a subset of all applicable members of the set. The phrase any integer derivable therein is intended to mean an integer between the corresponding numbers recited in the specification. The phrase any range derivable therein is intended to mean any range within such corresponding numbers. The term means, when followed by the term “for” is intended to mean hardware, firmware and/or software for achieving a result. The term step, when followed by the term “for” is intended to mean a (sub)method, (sub)process and/or (sub)routine for achieving the recited result. Unless otherwise defined, all technical and scientific terms used herein have the same meaning as commonly understood by one of ordinary skill in the art to which this present disclosure belongs. In case of conflict, the present specification, including definitions, will control.

The described embodiments and examples are illustrative only and not intended to be limiting. Although embodiments of the present disclosure can be implemented separately, embodiments of the present disclosure may be integrated into the system(s) with which they are associated. All the embodiments of the present disclosure disclosed herein can be made and used without undue experimentation in light of the disclosure. Embodiments of the present disclosure are not limited by theoretical statements (if any) recited herein. The individual steps of embodiments of the present disclosure need not be performed in the disclosed manner, or combined in the disclosed sequences, but may be performed in any and all manner and/or combined in any and all sequences. The individual components of embodiments of the present disclosure need not be combined in the disclosed configurations, but could be combined in any and all configurations.

Various substitutions, modifications, additions and/or rearrangements of the features of embodiments of the present disclosure may be made without deviating from the scope of the underlying inventive concept. All the disclosed elements and features of each disclosed embodiment can be combined with, or substituted for, the disclosed elements and features of every other disclosed embodiment except where such elements or features are mutually exclusive. The scope of the underlying inventive concept as defined by the appended claims and their equivalents cover all such substitutions, modifications, additions and/or rearrangements.

The appended claims are not to be interpreted as including means-plus-function limitations, unless such a limitation is explicitly recited in a given claim using the phrase(s) “means for” “mechanism for” and/or “step for”. Subgeneric embodiments of the invention are delineated by the appended independent claims and their equivalents. Specific embodiments of the invention are differentiated by the appended dependent claims and their equivalents.

What is claimed is:

1. A method, comprising: transferring a substrate from a loadlock into a thermal ramp chamber; then thermally processing the substrate in the thermal ramp chamber wherein the thermal ramp chamber includes a first independently controlled elemental reactant source containing and supplying vapor having both i) independent control of a total vapor pressure of a first elemental reactant containing vapor and ii) independent control of a partial vapor pressure of first elemental reactant vapor within the thermal ramp chamber; then transferring the substrate from the thermal ramp chamber to a thermal soak chamber; then soaking the substrate in the thermal soak chamber wherein the thermal soak chamber includes a second independently controlled elemental reactant source containing and supplying vapor having both i) independent control of a total vapor pressure of a second elemental reactant containing vapor and ii) independent control of a partial vapor pressure of a second elemental reactant vapor within the thermal soak chamber; then transferring the substrate from the thermal soak chamber to a cooling chamber; and then cooling the substrate in the cooling chamber wherein the cooling chamber includes a third independently controlled elemental reactant source containing and supplying vapor having both i) independent control of a total vapor pressure of a third elemental reactant containing vapor and ii) independent control of a partial vapor pressure of a third elemental reactant vapor within the cooling chamber.

2. The method of claim 1, wherein the first elemental reactant containing vapor is substantially the same as the second elemental reactant containing vapor and the first elemental reactant vapor is substantially the same as the second elemental reactant vapor.

3. The method of claim 1, wherein the second elemental reactant containing vapor is substantially the same as the third elemental reactant containing vapor and the second elemental reactant vapor is substantially the same as the third elemental reactant vapor.

4. The method of claim 1, wherein the thermal ramp chamber is a rapid thermal ramp chamber.

5. The method of claim 1, wherein the cooling chamber includes an indirect cooling chamber and transferring the substrate from the thermal soak chamber to the cooling chamber includes transferring a thermal buffer surrounding the substrate.

6. The method of claim 5, further comprising transferring the substrate from the indirect cooling chamber to a direct cooling chamber.

7. The method of claim 1 wherein the first elemental reactant vapor includes at least one member selected from the group consisting of selenium, sulfur and/or sodium, the second elemental reactant vapor includes at least one member selected from the group consisting of selenium, sulfur and/or sodium, the third elemental reactant vapor includes at least one member selected from the group consisting of selenium, sulfur and/or sodium and the film includes at least one member selected from the group consisting of copper, indium, gallium and/or selenium.

8. An apparatus, comprising:
a thermal ramp chamber including a first independently controlled elemental reactant source containing and supplying vapor having both i) independent control of a total vapor pressure of a first elemental reactant containing vapor and ii) independent control of a partial vapor pressure of a first elemental reactant vapor within the thermal ramp chamber;
a thermal soak chamber coupled to the thermal ramp chamber, the thermal soak chamber including a second independently controlled elemental reactant source containing and supplying vapor having both i) independent control of a total vapor pressure of a second elemental reactant containing vapor and ii) independent control of a partial vapor pressure of a second elemental reactant vapor within the soak chamber; and
a cooling chamber coupled to the thermal soak chamber, the cooling chamber including a third independently controlled elemental reactant source containing and supplying vapor having both i) independent control of a total vapor pressure of a third elemental reactant containing vapor and ii) independent control of a partial vapor pressure of a third elemental reactant vapor within the cooling chamber.

9. The apparatus of claim 8, wherein the first elemental reactant containing vapor is substantially the same as the second elemental reactant containing vapor and the first elemental reactant vapor is substantially the same as the second elemental reactant vapor.

10. The apparatus of claim 8, wherein the second elemental reactant containing vapor is substantially the same as the third elemental reactant containing vapor and the second elemental reactant vapor is substantially the same as the third elemental reactant vapor.

11. The apparatus of claim 8, wherein the thermal ramp chamber includes a rapid thermal ramp chamber.

12. The apparatus of claim 8, wherein the cooling chamber includes an indirect cooling chamber including a thermal buffer surrounding a substrate carrier.

13. The apparatus of claim 12, further comprising a direct cooling chamber coupled to the indirect cooling chamber.

14. A method, comprising:
transferring a substrate from a loadlock into a thermal ramp chamber; then
thermally processing the substrate in the thermal ramp chamber; then
transferring the substrate from the thermal ramp chamber into a thermal soak chamber; then
soaking the substrate in the thermal soak chamber; then
transferring the substrate from the thermal soak chamber into an indirect cooling chamber; and then
cooling the substrate on the substrate carrier in the indirect cooling chamber while the substrate is located within a thermal buffer that surrounds the substrate carrier.

15. The method of claim 14, wherein the thermal ramp chamber includes a first independently controlled elemental reactant source containing and supplying vapor having both i) independent control of a total vapor pressure of a first elemental reactant containing vapor and ii) independent control of a partial vapor pressure of first elemental reactant vapor within the thermal ramp chamber.

16. The method of claim 15, wherein the thermal soak chamber includes a second independently controlled elemental reactant source containing and supplying vapor having both i) independent control of a total vapor pressure of a second elemental reactant containing vapor and ii) independent control of a partial vapor pressure of a second elemental reactant vapor within the thermal soak chamber.

17. The method of claim 16, wherein the first elemental reactant containing vapor is substantially the same as the second elemental reactant containing vapor and the first elemental reactant vapor is substantially the same as the second elemental reactant containing vapor.

18. The method of claim 17, wherein the cooling chamber includes a third independently controlled elemental reactant source containing and supplying vapor having both i) independent control of a total vapor pressure of a third elemental reactant containing vapor and ii) independent control of a partial vapor pressure of a third elemental reactant vapor within the cooling chamber.

19. The method of claim 18, wherein the second elemental reactant containing vapor is substantially the same as the third elemental reactant containing vapor and the second elemental reactant vapor is substantially the same as the third elemental reactant vapor.

20. The method of claim 14, wherein the thermal ramp chamber is a rapid thermal ramp chamber.

21. The method of claim 14, wherein the cooling chamber is an indirect cooling chamber and transferring the substrate from the thermal soak chamber to the cooling chamber includes transferring a thermal buffer surrounding the substrate.

22. The method of claim 21, further comprising transferring the substrate from the indirect cooling chamber to a direct cooling chamber.

23. The method of claim 14, wherein the first elemental reactant vapor includes at least one member selected from the group consisting of selenium, sulfur and/or sodium, the second elemental reactant vapor includes at least one member selected from the group consisting of selenium, sulfur and/or sodium, the third elemental reactant vapor includes at least one member selected from the group consisting of selenium, sulfur and/or sodium and the film includes at least one member selected from the group consisting of copper, indium, gallium and/or selenium.

24. An apparatus, comprising:
a thermal ramp chamber;
a thermal soak chamber coupled to the thermal ramp chamber; and
an indirect cooling chamber coupled to the thermal soak chamber, the indirect cooling chamber including a thermal buffer that includes a substrate carrier.

25. The apparatus of claim 24, wherein the thermal ramp chamber includes a first independently controlled elemental reactant source containing and supplying vapor having both i) independent control of a total vapor pressure of a first elemental reactant containing vapor and ii) independent control of a partial vapor pressure of first elemental reactant vapor within the thermal ramp chamber.

26. The apparatus of claim 25, wherein the thermal soak chamber includes a second independently controlled elemental reactant source containing and supplying vapor having both i) independent control of a total vapor pressure of a second elemental reactant containing vapor and ii) independent control of a partial vapor pressure of a second elemental reactant vapor within the thermal soak chamber.

27. The apparatus of claim 26, wherein the first elemental reactant containing vapor is substantially the same as the second elemental reactant containing vapor and the first elemental reactant vapor is substantially the same as the second elemental reactant vapor.

28. The apparatus of claim 27, wherein the indirect cooling chamber includes a third independently controlled elemental reactant source containing and supplying vapor having both i) independent control of a total vapor pressure of a third elemental reactant containing vapor and ii) independent control of a partial vapor pressure of a third elemental reactant vapor within the indirect cooling chamber.

29. The apparatus of claim 28, where the second elemental reactant containing vapor is substantially the same as the third elemental reactant containing vapor and the second elemental reactant vapor is substantially the same as the third elemental reactant vapor.

30. The apparatus of claim 24, wherein the thermal ramp chamber includes a rapid thermal ramp chamber.

31. The apparatus of claim 24, further comprising a direct cooling chamber coupled to the indirect cooling chamber.
